(19) United States
(12) Patent Application Publication
(10) Pub. No.: US 2005/0103274 A1
(43) Pub. Date: May 19, 2005

(54) Reliability assessment system and method

(76) Inventors: Cheng-Tsung Yu, Tainan (TW); Wu-Hsing Lin, Yunlin (TW); Jen-Tung Huang, Kaohsiung (TW); Zhi-Jen Cai, Taoyuan (TW); Zhen Qu, Miaoli (TW)

Correspondence Address: BIRCH STEWART KOLASCH & BIRCH, PO BOX 747, FALLS CHURCH, VA, 22040-0747, US

(21) Appl. No.: 10/712,108

(22) Filed: Nov. 14, 2003

(51) Int. Cl. C23C 16/00

(52) U.S. Cl. 118/728

(57) ABSTRACT

A pedestal supporting a substrate in a plasma chamber. The pedestal includes an insulating base, a conductive layer overlying the insulating base, and a ceramic cover incompletely covering the conductive layer. The conductive layer is covered when the pedestal supports the substrate.

### BACKGROUND

The present invention relates to a semiconductor fabrication apparatus, and more specifically to a pedestal supporting a substrate in a plasma chamber.

Referring to FIG. 1, the operation of a conventional pedestal 100 in a plasma chamber 200 is shown. FIG. 1 further shows a fabricating step of a substrate 10 cleaning the oxide thereon, such as cleaning oxide from a metal layer (not shown) of the substrate 10 exposed by a via (not shown).

In FIG. 1, pedestal 100 has an insulating base 114, a conductive layer 120, and an insulating cover 112. The insulating base 114 is usually silicon oxide, with a recess 115 embedded in the conductive layer 120. The insulating cover 112 is usually quartz, a solid phase of silicon oxide. The insulating cover 112 is usually a consumable part overlying the conductive layer 120 and insulating base 114 to support the substrate 10. A top view of the pedestal 100 is shown in FIG. 2. Pinhole 102 includes a pin (not shown) for loading and unloading the substrate 10. The range of dotted circle 117 shows the position of the conductive layer in pedestal 100. FIG. 1 is a sectional view of the conventional pedestal 100 along the AA line in FIG. 2.

The plasma chamber 200 in FIG. 1 further has a belljar 220 of quartz as a chamber wall, and a gas dispenser or shower head 240 electrically connected to a power supply 232. The conductive layer 120 also electrically connects with a power supply 234. When the power supplies 232 and 234 are engaged, argon gas (not shown) passing through the gas dispenser 240 is ionized to inert plasma 42. Power supplies 232 and 234 further drive inert plasma 42 to bombard the surface of substrate 10 to etch the oxide to a predetermined thickness. Moreover, because quartz is a solid phase of silicon oxide, belljar 220 can contribute to attachment of the oxide particles, formed during the plasma process shown in FIG. 1, to prevent substrate 10 from contamination by oxide particles.

When substrate 10 is an eight-inch wafer, the pedestal 100 is approximately 9 inches wide and the conductive layer 120 approximately 190 mm wide, less than the diameter of substrate 10. Inert plasma 42 usually bombards the surface of substrate 10 vertically and uniformly during the plasma process shown in FIG. 1. However, the design of the pedestal 100, in which the width of conductive layer 120 is less than the diameter of substrate 10, makes denser inert plasma 42 bombard the surface of substrate 10 nonvertically, resulting in abnormal etching of the insulating cover 112. The recess 116 in FIGS. 1 and 2 is formed by abnormal etching of the insulating cover 112. This shortens the lifetime of insulating cover 112. The abnormal etching of the insulating cover 112 is an additional source of more silicon-oxide particles, potentially contaminating the surface of substrate 10, negatively affecting yield of the plasma process and product reliability. The formation of recess 116 further causes deviation in impedance of insulating cover 112, negatively affecting etching stability of substrate 10 during the cleaning process.

Techniques have been developed to address particle reduction on the surface of substrate 10 during the plasma process shown in FIG. 1.

Su et al., in U.S. Pat. No. 5,410,122, disclose particles formed during the plasma process falling to the surface of substrate 10 at the end of the plasma process resulting from dissipation of charge on substrate 10 when power supplies 232 and 234 are turned off at the end of the plasma process. Thus, they disclose a technique to repel particles from the surface of substrate 10 in plasma chamber 200 by inducing positive or negative charge, or alternating charge, on substrate 10 without generating plasma thereabove. The repelled particles are then swept away by a horizontal force such as a high-rate gas flow or a magnetic field.

U.S. Pat. No. 6,423,175 discloses a technique performing mechanical sand-blasting or chemical etching on a focus ring (contributive to the focus of the inert plasma 42) (not shown) to increase the surface roughness of the focus ring, improving adhesion between the focus ring and the particles formed during the plasma process shown in FIG. 1.

Lu et al., in U.S. Pat. No. 6,482,331, disclose the temperature of belljar 220 rapidly cooling below 100° C. at the end of the plasma process. The contraction of particles adhered to the belljar 220 causes them to peel off from belljar 220 and fall on substrate 10, causing serious contamination. Therefore, U.S. Pat. No. 6,482,331 discloses a technique to heat belljar 220 using a heated gas such as nitrogen, to between about 100° C. and 150° C., flowing over belljar 220.

U.S. Pat. No. 6,551,520 discloses a technique setting a passageway (not shown) surrounding the bottom of pedestal 100 to attract the processing gas during the plasma process shown in FIG. 1. The particles formed during the plasma process are therefore removed into the passageway. Thus, particle contamination on substrate 10 is reduced.

The aforementioned disclosures can reduce the particle contamination on substrate 10 effectively, but cannot reduce the particle source resulting from abnormal etching of the insulating cover 112. A solution to the shortened lifetime of insulating cover 112 and unstable etching rate of substrate 10 during the plasma process resulting from abnormal etching is also not disclosed.

### SUMMARY

Thus, objects of the present invention are to provide a pedestal supporting a substrate in a plasma chamber, reducing particles formed in the plasma chamber, thereby preventing abnormal etching of a part of the pedestal to prolong its lifetime, and normalizing the etching rate on the substrate in the plasma chamber.

In order to achieve the described objects, the present invention provides a pedestal supporting a substrate in a plasma chamber. The pedestal includes an insulating base, conductive layer, and a ceramic cover. The conductive layer overlies the insulating base. The ceramic cover partially covers the conductive layer, which is covered when the pedestal supports the substrate.

Further scope of the applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention can be more fully understood by reading the subsequent detailed description in conjunction with the examples and references made to the accompanying drawings, which are given by way of illustration only, and thus are not limitative of the present invention, and wherein:

FIG. 1 is a cross-sectional view illustrating the operation of a conventional pedestal in a plasma chamber.

FIG. 2 is a top view of the conventional pedestal in FIG. 1.

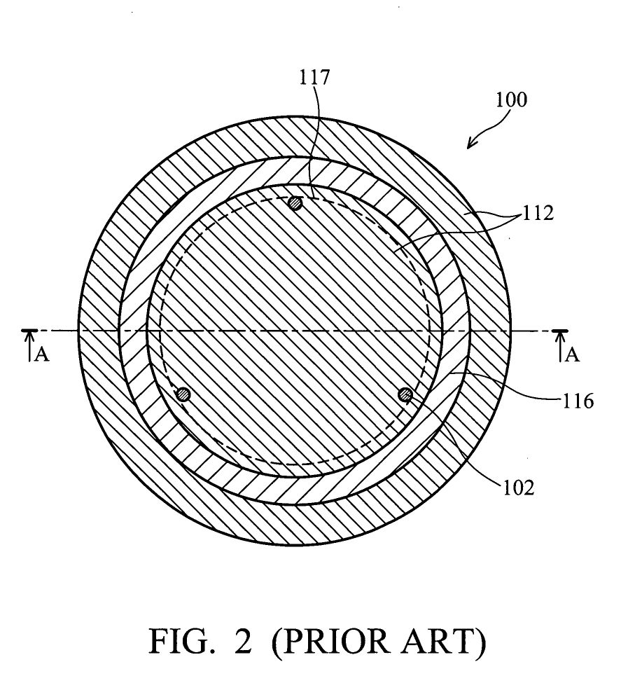

FIG. 3 is a cross-sectional view illustrating the operation of a pedestal supporting a substrate in a plasma chamber in accordance with a preferred embodiment of the present invention.

FIG. 4 is a top view of the pedestal in FIG. 3.

FIG. 5 is a control chart illustrating the difference between particle contamination with a conventional pedestal and that of the present invention.

FIGS. 6A and 6B are control charts illustrating the difference between etching thickness with a conventional pedestal and that of the present invention.

### DESCRIPTION

The following embodiment is intended to illustrate the invention more fully without limiting the scope of the claims, since numerous modifications and variations will be apparent to those skilled in this art.

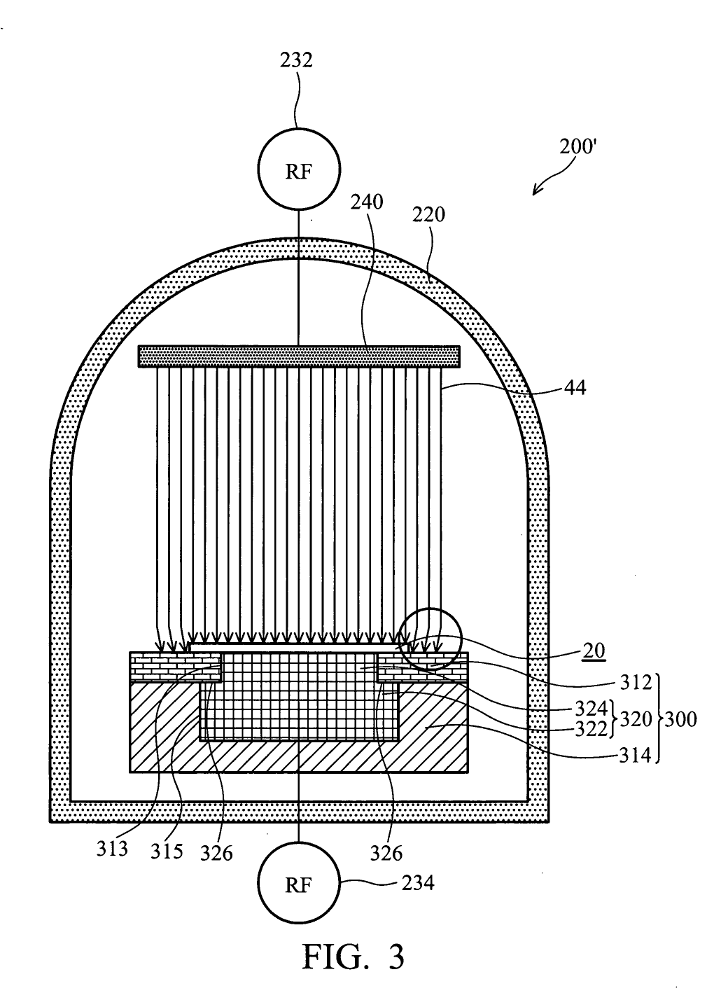

In FIG. 3, the operation of a pedestal 300 supporting a substrate 20 in a plasma chamber 200′ of the present invention is shown. In this embodiment, substrate 20 is processed in the metallization of a semiconductor fabricating process to clean excess oxide from the via of substrate 20, using an inert plasma 44, preferably argon. Note that the via cleaning step is an example, and is not intended to limit the scope of the present invention. Those skilled in the art will recognize the possibility for use of pedestal 300 of the present invention in any plasma chamber to process any fabrication step.

The pedestal 300 has an insulating base 314, conductive layer 320, and ceramic cover 312. The conductive layer 320 overlies the insulating base 314. The ceramic cover 312, completely or partially, but preferably partially, covers the conductive layer 320. The conductive layer 320, usually a titanium layer, is preferably covered when pedestal 300 supports substrate 20 in order to prevent the conductive layer 320 from etching due to the bombardment of inert plasma 44 during processing. When the conductive layer 320 is etched, inert plasma 44 becomes unstable and new particles comprising the composition of conductive layer 320 will be formed. The insulating base 314 usually has a recess 315. The conductive layer 320 usually has a bottom portion 322 embedded in recess 315 and upper portion 324 narrower than the bottom portion 322 protruding from recess 315, forming a shoulder 326 at the boundary of the bottom portion 322 and upper portion 324 of conductive layer 320. The ceramic cover 312 may further overlie the shoulder 326 of conductive layer 320. The ceramic cover 312, preferably including a composition of aluminum oxide, usually has a hollow portion 313 accommodating the upper portion 324 of conductive layer 320. The hollow portion 313 of ceramic layer 312 preferably has an opening exposing the upper portion 324 of conductive layer 320. It is necessary for the upper portion 324 of conductive layer 320 to be narrower than the diameter of substrate 20 when the upper portion 324 is exposed, in order to keep the upper portion 324 covered when supporting wafer 20.

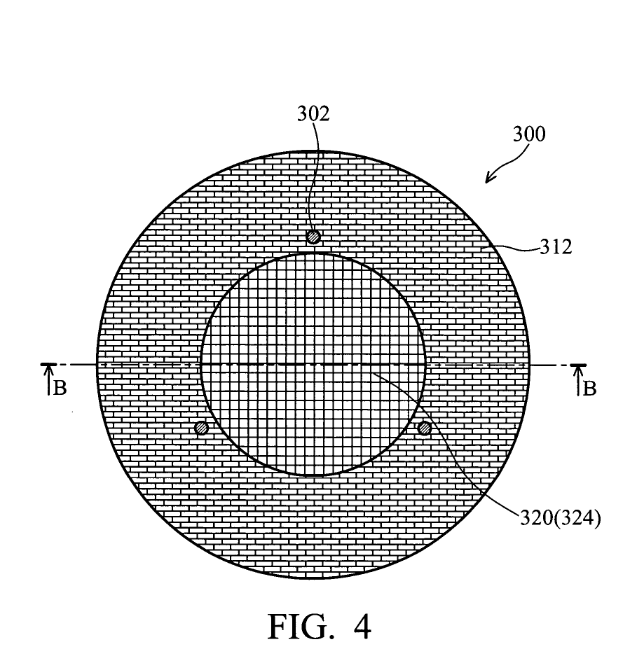

In FIG. 4, a top view of pedestal 300 and upper portion 324 of conductive layer 320 of the present invention shows that both are circular, but any desired shape is possible. Pinhole 302 includes a pin (not shown) for loading and unloading substrate 20. Moreover, FIG. 4 is a cross-sectional view of the pedestal 300 along the BB line in FIG. 3.

Next, in the via cleaning step of substrate 20 in plasma chamber 200′, a robot arm (not shown) transports a substrate 20 from an incoming wafer cartridge (not shown) to pedestal 300. When loading substrate 20, the pin is raised from pinhole 302 to receive substrate 20 from the robot arm and then returns to pinhole 302, locating substrate 20 on pedestal 300. At this time, conductive layer 320 is completely covered. Next, argon gas (not shown) passes through gas dispenser 240 and power supplies 232 and 234 are turned on, forming the inert plasma 44, which bombards the surface of substrate 20 to etch excess oxide therefrom. Argon gas supply stops and power supplies 232 and 234 are turned off. Finally, the pin is raised to elevate the substrate 20 and the robot arm transports substrate 20 from pedestal 300 to an outgoing wafer cartridge (not shown).

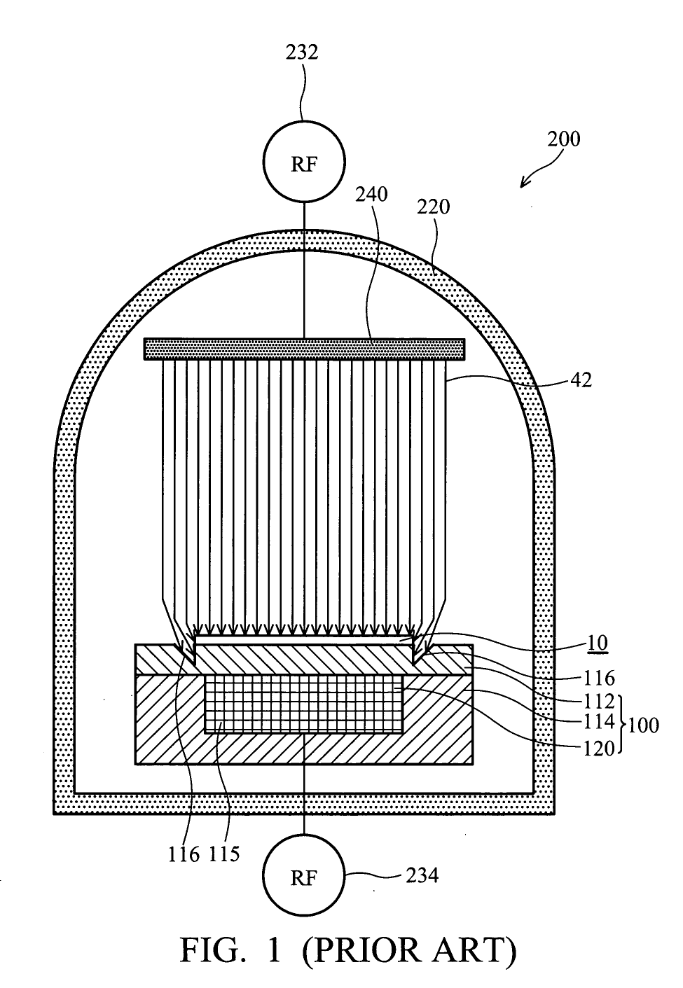

Because conductive layer 320, specifically the bottom portion 322, is narrower than the diameter of substrate 20, denser inert plasma 44 bombards the surface of substrate 20 nonvertically during the via cleaning step. However, the ceramic cover 312 has higher resistance to the bombardment. Thus, ceramic cover 312 is not overly etched. No apparent recess such as recess 116 in FIG. 1 is formed around substrate 20 on ceramic cover 312, thereby effectively prolonging the lifetime of the ceramic cover and lowering the PM frequency of plasma chamber 220. Further, few, if any, particles are formed during etching of ceramic cover 312, reducing, or altogether avoiding, contamination of substrate 20. Furthermore, impedance of ceramic cover 312 is stabilized since no apparent recess is formed, normalizing the etching rate of substrate 20 during via cleaning.

The lifetime of a quartz insulating cover 112 in FIG. 1 is approximately 16,000 process cycles. The lifetime of ceramic cover 312 of this embodiment is approximately 80,000 process cycles, an effective improvement. Further, the quartz insulating cover 112 can be recycled only once, and then is discarded. The ceramic cover 312 can be recycled more than eight times. Taking the other costs into consideration, even though the unit cost of ceramic cover 312 is higher than the quartz insulating cover 112, processing costs per wafer using the quartz insulating cover 112 are considerably higher than those with ceramic cover 312. Thus, the present invention further contributes to lower processing costs.

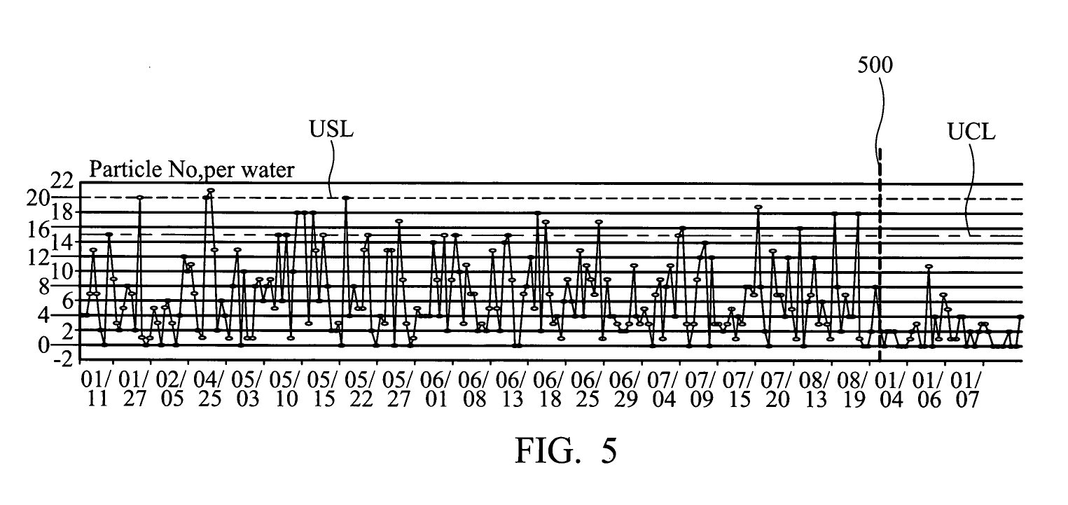

In FIG. 5, a control chart illustrates the difference between particle contamination with the conventional pedestal 100 in FIG. 1 and the pedestal 300 of the present invention. The left side of line 500 shows process data of particles per wafer after via cleaning with conventional pedestal 100. The right side of line 500 shows process data of particles per wafer after via cleaning with pedestal 300 of the present invention. With conventional pedestal 100, the control chart shows that more particles per wafer and frequencies exceed UCL (upper control limit) and even the USL (upper specification limit). With pedestal 300 of the present invention, the control chart shows fewer particles per wafer. More specifically, the average particle count per wafer is 6.7 with pedestal 100 and 1.9 with pedestal 300, a significant reduction.

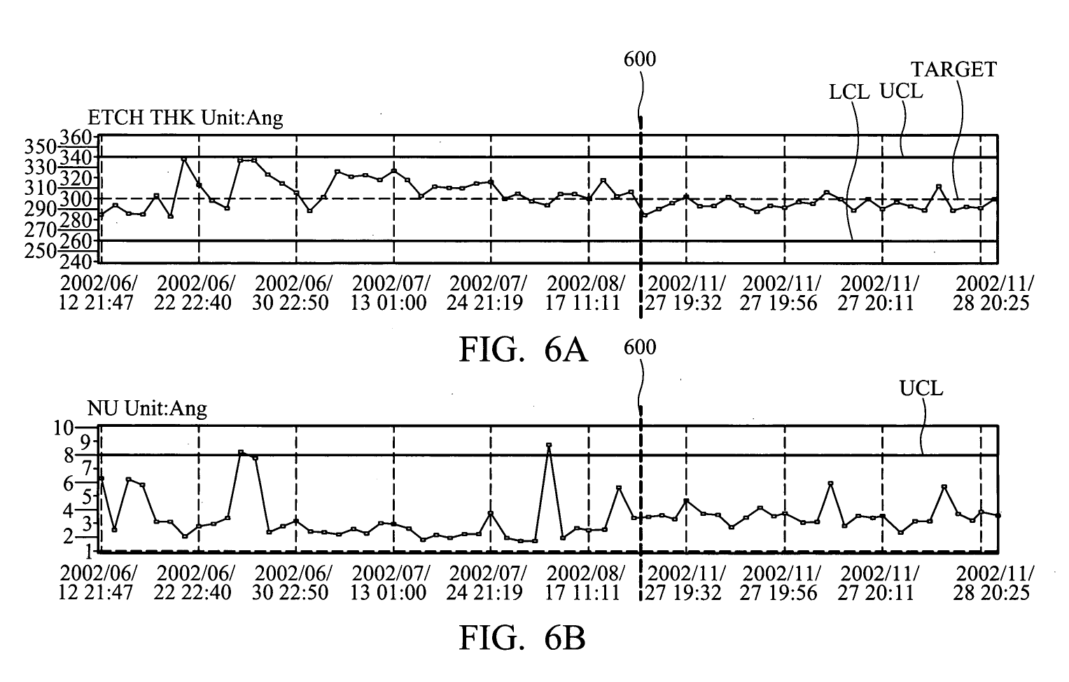

FIG. 6A is a control chart illustrating the difference between etching thickness with conventional pedestal 100 and with pedestal 300 of the present invention. The left side of line 600 shows process data of etching thickness after via cleaning with conventional pedestal 100. The right side of line 600 shows process data of etching thickness after via cleaning with pedestal 300 of the present invention. With conventional pedestal 100, the control chart shows that data deviation is higher with some data far from the target value of 300 A, further almost exceeding the UCL. With pedestal 300 of the present invention, the control chart shows lower data deviation with most of the data near the target value of 300 Å, demonstrating a more stable and balanced etching rate during via cleaning.

In FIG. 6B, a control chart illustrates comparison between wafer planarity with the conventional pedestal 100 and pedestal 300 of the present invention. The left side of line 600 shows process data of wafer planarity after via cleaning with conventional pedestal 100. The right side of line 600 shows process data of wafer planarity after via cleaning with pedestal 300 of the present invention. With conventional pedestal 100, data deviation is larger with some data exceeding the UCL. With pedestal 300 of the present invention, the control chart shows lower data deviation with no data exceeding the UCL, further demonstrating the increased stability and balance of etching rate during via cleaning.

Thus, the results show the efficacy of the inventive pedestal at reducing particle formation in the plasma chamber, thereby preventing pedestal from abnormal etching, prolonging its lifetime, and normalizing the etching rate on the substrate in the plasma chamber, which achieve the desired objects of the present invention.

Although the present invention has been particularly shown and described with reference to the preferred specific embodiments and examples, it is anticipated that alterations and modifications thereof will no doubt become apparent to those skilled in the art. It is therefore intended that the following claims be interpreted as covering all such alteration and modifications as fall within the true spirit and scope of the present invention.

1. A pedestal supporting a substrate in a plasma chamber, comprising:
an insulating base;
a conductive layer on the insulating base; and
a ceramic cover at least partially covering the conductive layer, the conductive layer being covered when the pedestal supports a substrate.

2. The pedestal in claim 1, wherein the conductive layer further comprises a bottom portion with a bottom width and an upper portion with an upper width, the upper width being less than the bottom width and a diameter of the substrate.

3. The pedestal in claim 2, wherein the insulating base further comprises a recess accommodating the bottom portion of the conductive layer.

4. The pedestal in claim 1, wherein the ceramic cover further overlies the insulating base.

5. The pedestal in claim 1, wherein the ceramic cover further comprises an opening exposing the conductive layer.

6. The pedestal in claim 2, wherein the ceramic cover overlies the bottom portion of the conductive layer and further comprises a hollow portion accommodating the upper portion of the conductive layer.

7. The pedestal in claim 1, wherein the ceramic cover is ring-shaped.

8. The pedestal in claim 1, wherein the insulating base comprises silicon oxide.

9. The pedestal in claim 1, wherein the conductive layer comprises titanium.

10. The pedestal in claim 1, wherein the ceramic cover comprises aluminum oxide.

11. A pedestal supporting a substrate in a plasma chamber, comprising:
an insulating base having a recess;
a conductive layer embedded in the recess; and
a ceramic cover overlying the insulating base and partially covering the conductive layer;
wherein the conductive layer is covered when the pedestal supports a substrate.

12. The pedestal in claim 11, wherein the conductive layer further comprises an upper portion, with a width less than the diameter of the substrate, protruding from the recess.

13. The pedestal in claim 11, wherein the conductive layer further comprises an upper portion, with a width less than the diameter of the substrate and the width of the other portion of the conductive layer, protruding from the recess.

14. The pedestal in claim 13, wherein the ceramic cover further comprises a hollow portion accommodating the upper portion of the conductive layer.

15. The pedestal in claim 13, wherein the ceramic cover further comprises a hollow portion accommodating the upper portion of the conductive layer and exposing the narrower upper portion of the conductive layer.

16. The pedestal in claim 11, wherein the ceramic cover is ring-shaped.

17. The pedestal in claim 11, wherein the insulating base comprises silicon oxide.

18. The pedestal in claim 11, wherein the conductive layer comprises titanium.

19. The pedestal in claim 11, wherein the ceramic cover comprises aluminum oxide.

20. A pedestal supporting a substrate in a plasma chamber, comprising:
a silicon-oxide base having a recess;
a titanium layer having a bottom portion embedded in the recess, and an upper portion, narrower than the bottom portion and the substrate, protruding from the recess; and
a ring-shaped ceramic cover, having a hollow portion accommodating the upper portion of the titanium layer therein, overlying the insulating base and a portion of the bottom portion of the titanium layer;
wherein the conductive layer is covered when the pedestal supports the substrate.

21. The method as claimed in claim 20, wherein the hollow portion of the ceramic cover further exposes the upper portion of the titanium layer.

22. The pedestal in claim 20, wherein the ceramic cover comprises aluminum oxide.
